(19) United States
(12) Patent Application Publication
(10) Pub. No.: US 2022/0367363 A1
(43) Pub. Date: Nov. 17, 2022

(54) LTCC ELECTRONIC DEVICE UNIT STRUCTURE

(71) Applicant: Chun-Hsia Chen, Taoyuan City (TW)

(72) Inventor: Chun-Hsia Chen, Taoyuan City (TW)

(73) Assignee: ONANO INDUSTRIAL CORP., Taoyuan City (TW)

(21) Appl. No.: 17/322,884

(22) Filed: May 17, 2021

(51) Int. Cl. H01L 23/538; H05K 1/03; H05K 3/46; H01L 23/31; H01L 23/00

(52) U.S. Cl. CPC H01L 23/5383; H05K 1/0306; H05K 3/4629; H01L 23/3178; H01L 24/29; H01L 2924/09701; H01L 2924/01047

(57) ABSTRACT

A low temperature co-fired ceramic (LTCC) electronic device includes a template layer, a base layer and a conductor. The template layer and the base layer are ceramic layers. The template layer has an electrode pattern formed by a hollow groove. A depth of the hollow groove is between 10 μm and 120 μm, and a width of the hollow groove is above 80 μm. The base layer is closely overlapped with the template layer. An overlapping area range of the base layer and the template layer at least covers the electrode pattern. The conductor is filled in the hollow groove of the electrode pattern. A filling thickness of the conductor is above 10 μm.

### BACKGROUND

### Technical Field

The invention relates to electronic devices made by the low temperature co-fired ceramic technique.

### Related Art

The low temperature co-fired ceramic technique (LTCC) has been widely applied to portable products that emphasize compactness and is a technologic trend of wireless communication modules. The LTCC process embeds various passive components, such as low-capacitance capacitors, resistors, filters, impedance converter, couplers, etc., into a multi-layer ceramic substrate and uses the printing-coating process to sinter to form an integrated ceramic part. As shown in FIG. 5, when a current LTCC technique is used to produce an electronic device, in the screen printing process, conductive glue is printed on a ceramic green embryo 800 to form a required electrode pattern 900, and solidified electrodes will be obtained after baking. A thickness of the electrodes formed by such a printing/coating manner can usually reach only about 10 μm. For those high power passive components such as couplers, whose electrode thickness must reach 40 μm or more, it cannot be done by the abovementioned process. Multiple printing and baking can be adopted to form an electrode pattern with a required thickness, but the electrode patter may have outward expansion and burrs. This will reduce the performance of the product of the electronic device or cause deformation or the electrode pattern or hollows of edges of the electrodes when the overlapping step of the LTCC process is implementing.

### SUMMARY

An object of the invention is to provide an improved low temperature co-fired ceramic (LTCC) electronic device unit structure, which can form an electrode pattern with a required electrode thickness. The ceramic green embryo is provided with an electrode pattern structure, which can be filled with conductive material.

To accomplish the above object, the improved low temperature co-fired ceramic (LTCC) electronic device unit structure of the invention includes a template layer, a base layer and a conductor. The template layer and the base layer are ceramic layers. The template layer has an electrode pattern formed by a hollow groove. A depth of the hollow groove is between 10 μm and 120 μm, and a width of the hollow groove is above 80 μm. The base layer is closely overlapped with the template layer. An overlapping area range of the base layer and the template layer at least covers the electrode pattern. The conductor is filled in the hollow groove of the electrode pattern. A filling thickness of the conductor is above 10 μm.

In the LTCC electronic device unit structure of the invention, a thickness of the template layer is between 10 μm and 120 μm, and a thickness of the base layer is between 10 μm and 250 μm.

In the LTCC electronic device unit structure of the invention, the hollow groove penetrates through an upper surface and a lower surface of the template layer, the conductor is formed by a liquid conductor precursor, and the conductor precursor contains conductive metal and solvent, and a material the conductive metal is selected from, but not limited to, one or a mixture of gold, silver and an alloy thereof. The selection depends on required specific properties such as resistivity, solder resistance, adhesion, migration resistance and similar characteristics.

In the LTCC electronic device unit structure of the invention, the conductor precursor is conductive glue with silver content of more than 80%.

### BRIEF DESCRIPTION OF THE DRAWINGS

FIG. 1 is a plan view of the template layer of the invention;

FIG. 2 is a cross-sectional view along line II-II in FIG. 1;

FIG. 3 is a cross-sectional view of the template layer and the base layer of the invention, which have been overlapped;

FIG. 4 is a cross-sectional view of the electronic device unit structure of the invention; and

FIG. 5 is a cross-sectional view of an electronic device unit structure made by a conventional art.

### DETAILED DESCRIPTION

A preferred embodiment of the improved low temperature co-fired ceramic (LTCC) electronic device unit structure with an electrode thickness of 40 μm of the invention are depicted in the drawings. To make the invention more understandable, some elements in the drawings are not drawn in an accurate scale and sizes of some elements are enlarged with respect to other elements. For the sake of clearness, irrelative details are not drawn.

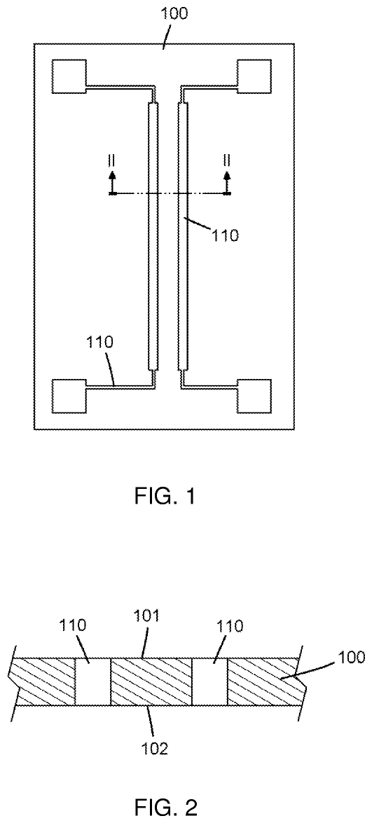

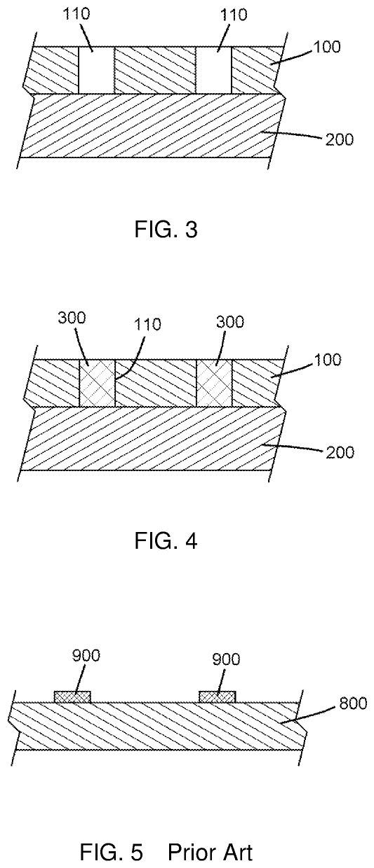

Please refer to FIGS. 1 and 2. The improved low temperature co-fired ceramic (LTCC) electronic device unit structure of the invention includes a template layer 100, a base layer 200 and a conductor 300. Considering the factors of low dielectric loss and conductor loss, the template layer 100 and the base layer 200 adopt a ceramic material with a low dielectric constant and a low dielectric loss. In the embodiment, the template layer 100 uses a ceramic green embryo with a thickness of about 40 μm. The template layer 100 is cut by a cutting machine (such as a die machine) to form a required electrode pattern. As shown in FIGS. 1 and 2, the electrode pattern includes at least one hollow groove 110. A width of the hollow groove 110 is above 80 μm, for example, 100 μm. The hollow groove 110 substantially penetrates through an upper surface 101 and a lower surface 102 of the template layer 100.

The base layer 200 is overlapped on the lower surface 102 of the template layer 100 by a laminating machine. An overlapping area range of the base layer 200 and the template layer 100 covers the electrode pattern to close the lower opening of the hollow groove 110. The base layer 200 provides support to the template layer 100 and enhance the overall structural strength. In the embodiment, a thickness of the base layer 200 is substantially identical to a thickness of the template layer 100.

Please refer to FIG. 4. The conductor 300 is formed in the hollow groove 110 of the template layer 100 and has a thickness that is substantially identical to a thickness of the template layer 100, i.e., the thickness of the conductor 300 is 40 μm. The conductor 300 is formed by filling the hollow groove 110 of the electrode pattern with a liquid conductor precursor such as conductive glue with silver (Ag) content of more than 80% and then baking the conductor precursor, so that a solidified conductor 300 can be formed in the hollow groove 110 and a required electrode pattern can be formed. Finally, the electronic device unit structure is implemented with sequential LTCC steps such as stacking, lamination, burn-out and sintering to finish the production of the whole electronic device unit structure.

In sum, the LTCC electronic device unit structure of the invention depends on a required electrode thickness of an electronic device to select a template layer with a thickness that is the same as or slightly greater than the required electrode thickness, cuts hollow grooves on the template layer to form an electrode pattern, presses and overlaps a base layer on a surface of the template layer, fills the hollow grooves with a conductive material with specific quantity, and finally bakes and dries the conductive material to form a conductor with a required thickness in the hollow grooves. As a result, an electrode pattern with an electrode thickness can be obtained. Accordingly, the invention is suitable for producing a high power electronic device with a higher electrode thickness.

It will be appreciated by persons skilled in the art that the above embodiment has been described by way of example only and not in any limitative sense, and that various alterations and modifications are possible without departure from the scope of the invention as defined by the appended claims.

What is claimed is:

1. A low temperature co-fired ceramic (LTCC) electronic device unit structure comprising:
a template layer, being a ceramic layer, having an electrode pattern formed by a hollow groove, a depth of the hollow groove being between 10 μm and 120 μm, and a width of the hollow groove being above 80 μm;
a base layer, being a ceramic layer, closely overlapped with the template layer, an overlapping area range of the base layer and the template layer at least covering the electrode pattern; and
a conductor, filled in the hollow groove, and a filling thickness of the conductor being above 10 μm.

2. The LTCC electronic device unit structure of claim 1, wherein a thickness of the template layer is between 10 μm and 120 μm.

3. The LTCC electronic device unit structure of claim 1, wherein a thickness of the base layer is between 10 μm and 250 μm.

4. The LTCC electronic device unit structure of claim 1, wherein the hollow groove penetrates through an upper surface and a lower surface of the template layer.

5. The LTCC electronic device unit structure of claim 1, wherein the conductor is formed by a liquid conductor precursor, and the conductor precursor contains conductive metal and a solvent.

6. The LTCC electronic device unit structure of claim 5, wherein a material the conductive metal is selected from one or a mixture of gold, silver and an alloy thereof.

7. The LTCC electronic device unit structure of claim 5, wherein the conductor precursor is conductive glue with silver content of more than 80%.
